(19) United States
(12) Patent Application Publication
(10) Pub. No.: US 2015/0070971 A1
(43) Pub. Date: Mar. 12, 2015

(54) RESISTANCE CHANGE MEMORY

(71) Applicants: Akira KATAYAMA, Seoul (KR); Masahiro TAKAHASHI, Seongnam-si (KR)

(72) Inventors: Akira KATAYAMA, Seoul (KR); Masahiro TAKAHASHI, Seongnam-si (KR)

(21) Appl. No.: 14/201,706

(22) Filed: Mar. 7, 2014

Related U.S. Application Data
(60) Provisional application No. 61/876,555, filed on Sep. 11, 2013.

(51) Int. Cl. G11C 13/00; G11C 11/16

(52) U.S. Cl. CPC G11C 13/004; G11C 11/1673
USPC 365/148; 365/158

(57) ABSTRACT

According to one embodiment, a resistance change memory includes the following structure. A memory cell includes a resistance change element and a transistor. A sense amplifier reads data stored in the memory cell. A control circuit controls the reading by the sense amplifier, and outputs a first signal to control the start of precharging of the bit line, a second signal to control a cell current running through the memory cell, and a third signal to control the start of the activation of the sense amplifier. A second word line has an interconnect structure similar to that of the first word line. A monitor circuit detects a first signal delay in the second word line, and outputs the first signal to the sense amplifier in accordance with the first signal delay.

### CROSS-REFERENCE TO RELATED APPLICATIONS

This application claims the benefit of U.S. Provisional Application No. 61/876,555, filed Sep. 11, 2013, the entire contents of which are incorporated herein by reference.

### FIELD

Embodiments described herein relate generally to a resistance change memory.

### BACKGROUND

Recently, attention has been focused on semiconductor memories that use, as a memory device, a nonvolatile memory such as a resistance change memory (e.g., a magnetoresistive random access memory: MRAM, a phase change random access memory: PRAM, or a resistive random access memory: ReRAM).

In the resistance change memory, the change of its resistance value caused by the application of a current (or voltage) is used to determine whether data is “1” or “0”. Thus, the resistance change memory includes a sense amplifier to sense a small current difference of a read current read from memory cells.

### BRIEF DESCRIPTION OF THE DRAWING

FIG. 1 is a diagram showing the configuration of a resistance change memory according to an embodiment;

FIG. 2 is a circuit diagram showing the configurations of a memory cell array and a sense amplifier according to the embodiment;

FIG. 3 is a diagram showing the timing of control signals in reading in the sense amplifier;

FIG. 4 is a schematic diagram showing the configurations of the memory cell array and peripheral circuits;

FIG. 5 is a diagram showing precharge timing in the circuits shown in FIG. 4;

FIG. 6 is a diagram showing the relation between a precharge time in the reading and a time before the start of the activation of the sense amplifier;

FIG. 7 is a diagram showing precharge timing in Proposed 1 of the embodiment;

FIG. 8 is a diagram showing precharge timing in Proposed 2 of the embodiment;

FIG. 9 is a schematic diagram showing the configurations of the memory cell array according to the embodiment and a monitor circuit according to Proposed 1;

FIG. 10 is a schematic diagram showing a first configuration example of the memory cell array according to the embodiment and the monitor circuit according to Proposed 2;

FIG. 11 is a schematic diagram showing a second configuration example of the memory cell array according to the embodiment and the monitor circuit according to Proposed 2; and

FIG. 12 is a schematic diagram showing a third configuration example of the memory cell array according to the embodiment and the monitor circuit according to Proposed 2.

### DETAILED DESCRIPTION

Hereinafter, a resistance change memory according to an embodiment will be described with reference to the drawings. In the following description, like reference signs are used for components having the same functions and configurations, and repeated explanations are given only when necessary. Embodiments shown below illustrate devices and methods which embody the technical concepts of the embodiment, and the materials, shapes, structures, and locations of the components are not specified as below.

In general, according to one embodiment, a resistance change memory includes a first memory cell, a sense amplifier, a control circuit, a second word line, and a first monitor circuit. The first memory cell includes a first resistance change element and a first transistor. The first memory cell is connected to a bit line, and the first transistor is connected to a first word line. The sense amplifier reads data stored in the first memory cell. The control circuit controls the reading by the sense amplifier. The control circuit outputs a first signal to control the start of precharging of the bit line, a second signal to control a cell current running through the first memory cell, and a third signal to control the start of the activation of the sense amplifier. The second word line has an interconnect structure similar to that of the first word line. The first monitor circuit detects a first signal delay in the second word line. The first monitor circuit outputs the first signal to the sense amplifier in accordance with the first signal delay.

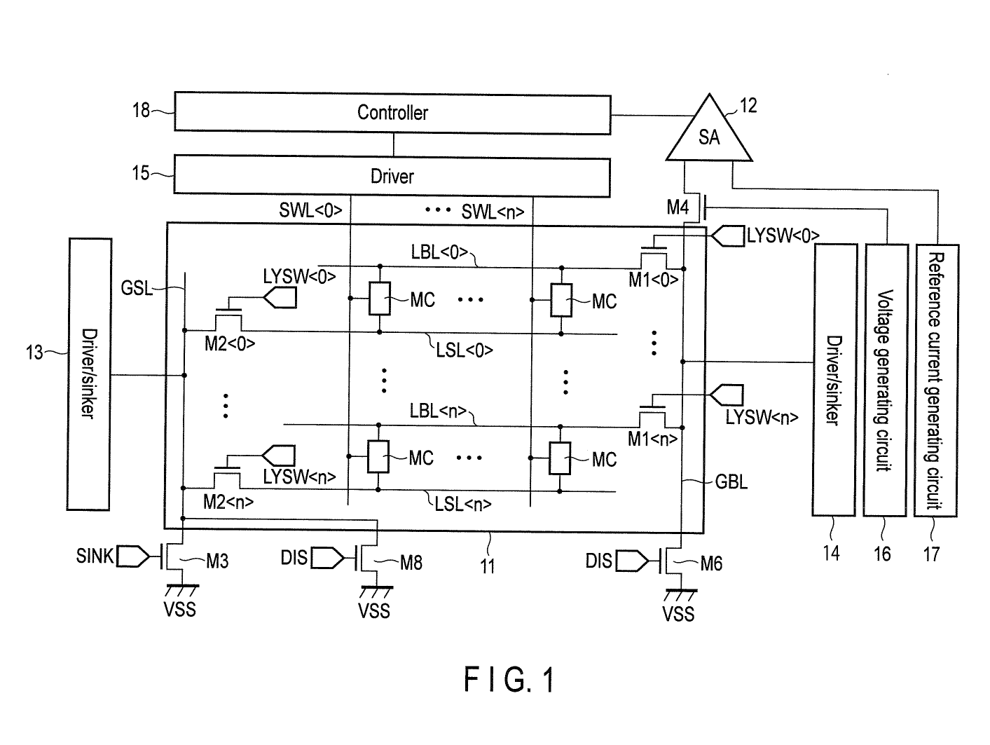

FIG. 1 is a diagram showing the configuration of a resistance change memory according to an embodiment.

The resistance change memory includes a memory cell array 11, a sense amplifier 12, drivers/sinkers 13 and 14, a driver 15, a voltage generating circuit 16, a reference current generating circuit 17, and a controller 18.

The memory cell array 11 has memory cells MC arranged in matrix form. The memory cells are connected between a local bit line LBL<0> and a local source line LSL<0>, between LBL<1> and LSL<1>, . . . , and between LBL<n> and LSL<n>. Further, the memory cells are respectively connected to sub word lines SWL<0> to SWL<n>. That is, the memory cells are respectively located at the intersections of the local bit lines LBL<0> to LBL<n>, the local source lines LSL<0> to LSL<n>, and the sub word lines SWL<0> to SWL<n>. Transistors which respectively select the sub word lines SWL<0> to SWL<n>, and main word lines connected to the sub word lines SWL<0> to SWL<n> via the transistors are provided, but are not shown here. n indicates 0, 1, 2, . . . , n.

The local bit lines LBL<0> to LBL<n> are connected at one end to a global bit line GBL via n-channel MOS field effect transistors (hereinafter referred to as nMOS transistors) M1<0> to M1<n>, respectively. Local column switch signals LYSW<0> to LYSW<n> are supplied to the gates of the nMOS transistors M1<0> to M1<n>, respectively. The local bit lines LBL<0> to LBL<n> are connected at the other end to the memory cells MC.

The global bit line GBL is connected to the driver/sinker 14. The global bit line GBL is also connected to the sense amplifier 12 via an nMOS transistor (clamp transistor) M4. The voltage generating circuit 16 which generates a predetermined voltage is connected to the gate of the nMOS transistor M4. The global bit line GBL is also connected to a reference voltage terminal, for example, a ground potential terminal Vss via an nMOS transistor (discharge transistor) M6. A discharge signal DIS is supplied to the gate of the nMOS transistor M6.

The local source lines LSL<0> to LSL<n> are connected at one end to a global source line GSL via nMOS transistors M2<0> to M2<n>, respectively. The local column switch signals LYSW<0> to LYSW<n> are supplied to the gates of the nMOS transistors M2<0> to M2<n>, respectively. The local source lines LSL<0> to LSL<n> are connected at the other end to the memory cells MC.

The global source line GSL is connected to the driver/sinker 13. The global source line GSL is also connected to the reference voltage terminal, for example, the ground potential terminal Vss via an nMOS transistor M3. A signal SINK is supplied to the gate of the nMOS transistor M3. The global source line GSL is also connected to the reference voltage terminal, for example, the ground potential terminal Vss via an nMOS transistor (discharge transistor) M8. The discharge signal DIS is supplied to the gate of the nMOS transistor M8.

The drivers/sinkers 13 and 14 pass a write current having a direction corresponding to write data through the memory cells MC during writing. The drivers/sinkers 13 and 14 thereby write into the memory cells MC.

The sub word lines SWL<0> to SWL<n> are connected to the driver 15 which drives the sub word lines.

The reference current generating circuit 17 which supplies a reference current to the sense amplifier 12 is connected to the sense amplifier 12. The controller 18 is connected to the sense amplifier 12. The controller 18 controls the operation of each component in the resistance change memory. For example, the controller 18 generates a control signal to be supplied to the sense amplifier 12, and controls standby and read operations in the sense amplifier 12.

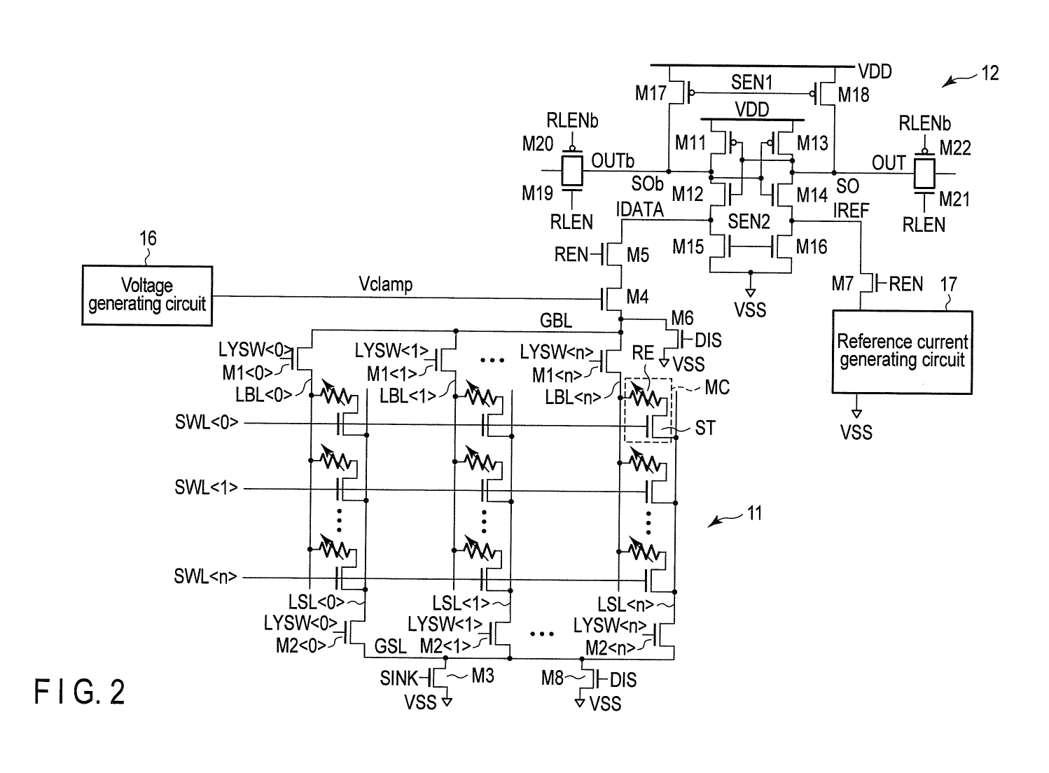

FIG. 2 is a circuit diagram showing the configurations of the memory cell array 11 and the sense amplifier 12 in FIG. 1.

The configuration of the memory cell array 11 is described below.

As described above, the memory cell array 11 has the memory cells arranged in matrix form at the intersections of the local bit lines LBL<0> to LBL<n>, the local source lines LSL<0> to LSL<n>, and the sub word lines SWL<0> to SWL<n>. n indicates 0, 1, 2, . . . , n.

The memory cell MC includes, for example, a resistance change element RE and a select transistor ST. The resistance change element RE is an element which is changed in resistance value by the application of at least one of a current (and a voltage). The resistance change element RE includes, for example, a magnetic tunnel junction (MTJ) element, a variable resistance element, a phase change element, or a ferroelectric element. The gate of the select transistor ST is connected to the sub word lines SWL. The memory cell MC is selected when the select transistor ST is turned on by the sub word line SWL.

The local bit lines LBL<0> to LBL<n> are connected at one end to the global bit line GBL via column selection transistors M1<0> to M1<n>, respectively. The local column switch signals LYSW<0> to LYSW<n> are supplied to the gates of the column selection transistors M1<0> to M1<n>, respectively.

Furthermore, the global bit line GBL is connected to a connection node between nMOS transistors M12 and M15 in the sense amplifier 12 via the clamp transistor M4 and an nMOS transistor (read enable transistor) M5 having current paths connected in series. The global bit line GBL is also connected to the ground potential terminal Vss via the nMOS transistor M6. The discharge signal DIS is supplied to the gate of the nMOS transistor M6.

The local source lines LSL<0> to LSL<n> are connected at one end to the global source line GSL via column selection transistors M2<0> to M2<n>, respectively. The local column switch signals LYSW<0> to LYSW<n> are supplied to the gates of the column selection transistors M2<0> to M2<n>, respectively.

The global source line GSL is connected to the ground potential terminal Vss via the nMOS transistor M3. A signal SINK is supplied to the gate of the nMOS transistor M3. The global source line GSL is also connected to the ground potential terminal Vss via the nMOS transistor M8. The discharge signal DIS is supplied to the gate of the nMOS transistor M8.

The configuration of the sense amplifier 12 is described below.

The sense amplifier 12 is a current detection sense amplifier. The sense amplifier 12 includes a first inverter, a second inverter, nMOS transistors M15 and M16, p-channel MOS field effect transistors (hereinafter referred to as pMOS transistors) M17 and M18, a first pass transistor, and a second pass transistor.

The first inverter includes a pMOS transistor M11 and an nMOS transistor M12. The first inverter has a first input terminal, a first output terminal, and first and second voltage terminals. The second inverter includes a pMOS transistor M13 and an nMOS transistor M14. The second inverter has a second input terminal, a second output terminal, and third and fourth voltage terminals. The second input terminal is connected to the first output terminal. The second output terminal is connected to the first input terminal.

The first pass transistor includes an nMOS transistor M19 and a pMOS transistor M20. The second pass transistor includes an nMOS transistor M21 and a pMOS transistor M22.

The drain of the pMOS transistor (sense enable transistor) M17 is connected to the first output terminal of the first inverter. The source of the pMOS transistor M17 is connected to a power supply voltage terminal VDD. The drain of the pMOS transistor (sense enable transistor) M18 is connected to the second output terminal of the second inverter. The source of the pMOS transistor M18 is connected to the power supply voltage terminal VDD. A sense enable signal SEN1 is supplied to the gates of the pMOS transistors M17 and M18 from the controller 18.

The drain of the nMOS transistor M15 is connected to the first voltage terminal of the first inverter (the source of the transistor M12). The source of the nMOS transistor M15 is connected to the ground potential terminal Vss. The drain of the nMOS transistor M16 is connected to a third voltage terminal of the second inverter (the source of the transistor M14). The source of the nMOS transistor M16 is connected to the ground potential terminal Vss. A sense enable signal SEN2 is supplied to the gates of the nMOS transistors M15 and M16 from the controller 18.

The first pass transistor (transistors M19 and M20) is connected to the first output terminal of the first inverter. Read line enable signals RLEN and RLENb are supplied to the gates of the transistors M19 and M20 from the controller 18, respectively.

The second pass transistor (transistors M21 and M22) is connected to the second output terminal of the second inverter. The read line enable signals RLEN and RLENb are supplied to the gates of the transistors M21 and M22 from the controller 18, respectively.

The first voltage terminal of the first inverter (the source of the transistor M12) is connected to the drain of the nMOS transistor M5. A read enable signal REN is supplied to the gate of the nMOS transistor M5 from the controller 18. The source of the nMOS transistor M5 is connected to the global bit line GBL via the nMOS transistor M4. The voltage generating circuit 16 is connected to the gate of the nMOS transistor M4.

The third voltage terminal of the second inverter (the source of the transistor M14) is connected to the reference current generating circuit 17 via an nMOS transistor (read enable transistor) M7. The read enable signal REN is supplied to the gate of the nMOS transistor M7 from the controller 18.

The voltage generating circuit 16 is connected to the gate of the nMOS transistor M4. The voltage generating circuit 16 supplies the gate of the clamp transistor M4 with a clamp voltage Vclamp (e.g., 0.1 to 0.6 V) which is a predetermined analog voltage during reading. Thus, the current running through the memory cells MC is limited to less than an upper limit to prevent the destruction of the data stored in the selected memory cells. The voltage generating circuit 16 also supplies the voltage Vclamp (“low”) to the gate of the clamp transistor M4 during standby to turn off (shut off) the clamp transistor M4.

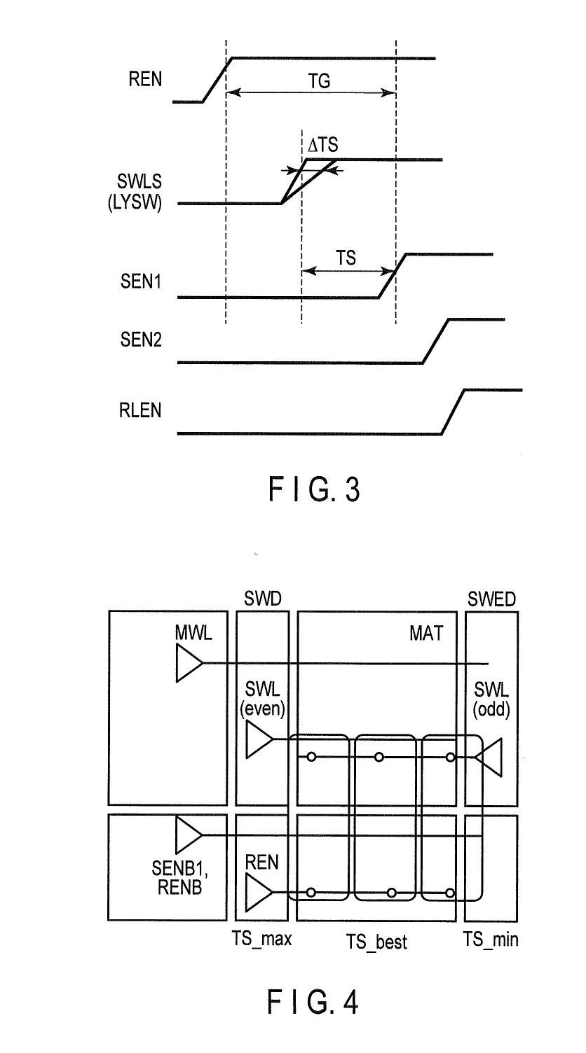

FIG. 3 is a diagram showing the timing of a control signal in reading in the sense amplifier.

During reading, the controller 18 outputs the control signal to the sense amplifier 12, and controls a read operation in the sense amplifier 12. The control signal includes the read enable signal REN, a sub word line signal SWLS, the local column switch signal LYSW, the sense enable signals SEN1 and SEN2, and the read line enable signal RLEN.

The read enable signal REN is a signal which decides the timing of connecting the sense amplifier 12 and the global bit line GBL. If this read enable signal REN becomes “high”, a constant current source is connected to the global bit line GBL, and precharging of the global bit line GBL is started. The precharging of the global bit line GBL is continued until the sense enable signal SEN1 becomes “high”.

The sub word line signal SWLS is a signal to turn on or off the select transistor ST which selects the memory cells. The local column switch signal LYSW is a signal to connect the global bit line GBL and the local bit line LBL and also connect the global source line GSL and the local source line LSL. If the sub word line signal SWLS and the local column switch signal LYSW become “high”, a cell current runs through the bit lines (the global bit line GBL and the local bit line LBL) and the memory cell (the resistance change element RE and the select transistor ST) MC. Thus, the data stored in the memory cell is output to the bit lines.

After the sub word line signal SWLS and the local column switch signal LYSW have become “high”, the sense enable signals SEN1 and SEN2 which activate the sense amplifier 12 are supplied. The sense enable signal SEN1 is a signal which decides the activation timing of the sense amplifier 12. The sense enable signal SEN2 is a signal which decides the data latch timing in the sense amplifier 12.

The read line enable signal RLEN is then supplied. The read line enable signal RLEN is a signal which decides the timing of outputting data to the outside from the sense amplifier 12.

The operation of precharging the bit line in the reading is described below.

As shown in FIG. 3, if the read enable signal REN rises to “high”, the nMOS transistors M5 and M7 are turned on, and the sense amplifier 12 and the global bit line GBL are electrically connected. As a result, the power supply voltage terminal VDD is supplied to the global bit line GBL, and then precharging of the global bit line GBL is started. At the same time, the sense enable signals SEN1 and SEN2 are “low”, the pMOS transistors M17 and M18 are on, and the nMOS transistors M15 and M16 are off. Moreover, the nMOS transistor M4 is on because of the voltage Vclamp.

If the sub word line signal SWLS and the local column switch signal LYSW then rise to “high”, the select transistor ST and the nMOS transistors M1 and M2 are turned on, and the bit lines (the global bit line GBL and the local bit line LBL) and the memory cell MC are electrically connected. As a result, a cell current IDATA runs through the memory cell MC from the bit lines. At the same time, the nMOS transistor M3 is on because of the sink signal SINK.

At the point where the cell current IDATA running through the memory cell MC has become stationary, the sense enable signal SEN1 then rises to “high”, and the pMOS transistors M17 and M18 are turned off. As a result, the supply of the power supply voltage terminal VDD to the bit line is stopped, and then the sense amplifier 12 is activated.

When the sense enable signal SEN2 rises to “high”, the nMOS transistors M15 and M16 are turned on. As a result, a latch circuit of the sense amplifier 12 is activated. That is, the cell current IDATA is compared with a reference current IREF passed by the reference current generating circuit 17, and the data stored in the memory cell MC is held in the latch circuit including the pMOS transistors M11 and M13 and the nMOS transistors M12 and M14. The reference current IREF is set to an intermediate value between the cell current of the memory cell in which “0” is stored and the cell current of the memory cell in which “1” is stored.

The sub word line SWL on which the sub word line signal SWLS (that may include the local column switch signal LYSW) is transmitted is relatively high in interconnect capacity as compared with interconnect lines on which the read enable signal REN and the sense enable signals SEN1 and SEN2 are transmitted, and therefore has a long signal delay time. Thus, the delay time of the sub word line signal SWLS depends on the place in a chip or in the memory cell array. Therefore, (a) a time TG from the start of the precharging of the bit line to the start of the activation of the sense amplifier and (b) a time TS from the start of the flow of the cell current (the activation of the selection transistor) to the start of the activation of the sense amplifier are different depending on the place in the chip or in the memory cell array.

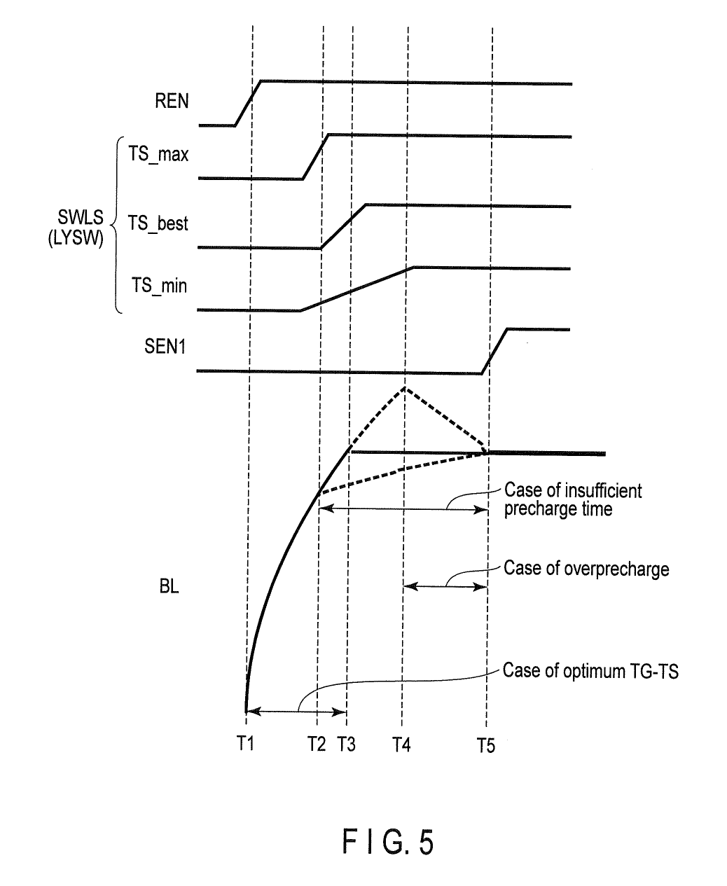

Now, problems of the precharging operation of the bit line are described in detail with reference to FIG. 4 and FIG. 5.

FIG. 4 is a schematic diagram showing the configurations of the memory cell array and peripheral circuits. FIG. 5 is a diagram showing the precharge timing in the circuits shown in FIG. 4 in reading.

As shown in FIG. 4, the sub word line SWL (even) driven from one side of the memory cell array and the sub word line SWL (odd) driven from the other side opposite to the one side are disposed for the memory cell array (referred to here as MAT). Sub word line drivers SWD which drive the sub word line SWL (even) and the sub word line SWL (odd) are disposed at one end and the other of the memory cell array. Moreover, a main word line MWL connected to the sub word lines SWL is disposed in the memory cell array, and a main word line driver which drives the main word line is disposed at the one end. Although not specifically illustrated in FIG. 4, interconnect lines of the local column switch signal LYSW may have an interconnect structure similar to that of the sub word lines SWL, and controlled.

An interconnect line on which the read enable signal REN is transmitted is disposed in the memory cell array, and a read enable buffer RENB and a sense enable buffer SENB1 are disposed at the one end.

The interconnect line on which the read enable signal REN is transmitted is configured to be distributed in the same direction as the sub word line SWL by the use of a metal interconnect line higher than the sub word line SWL. As described above, the sub word line SWL on which the sub word line signal SWLS (that may include the signal LYSW) is relatively high in interconnect capacity as compared with the interconnect lines on which the read enable signal REN and the sense enable signal SEN1 are transmitted, and produces a great difference of delay time depending on the distance from the sub word line driver SWD, as shown in FIG. 4. The time TS becomes TS_max, TS_best, and TS_min as the distance from the sub word line driver SWD increases. As described above, the time TS is the time extending from the start of the flow of the cell current to the start of the activation of the sense amplifier.

As shown in FIG. 5, if the time (hereinafter referred to as a precharge time) from the start of the precharging of the bit line to the start of the flow of the cell current (to the activation of the select transistor) is short (T1→T2), the cell current starts flowing early, and the time before the bit line potential reaches a stationary state is longer. On the other hand, when the precharge time is long (T1→T4), the bit line potential overshoots, and the time before the bit line potential is restored to the stationary state is longer.

Thus, the precharge time includes an optimum time (T1→T3) having no insufficient precharge or no excessive precharge. If the precharge time can be set to the optimum time, there is no insufficient precharge or no excessive precharge. Therefore, the time from the rising of the sub word line signal SWLS to the rising of the sense enable signal SEN1 can be set to a minimum time.

Thus, if the rise time (T5) of the sense enable signal SEN1 can be earlier, the subsequent rising of the sense enable signal SEN2 and the read line enable signal RLEN can also be earlier. Consequently, the reading operation by the sense amplifier 12 can be faster, and the time required from the input of a read command to the output of the memory data can be reduced.

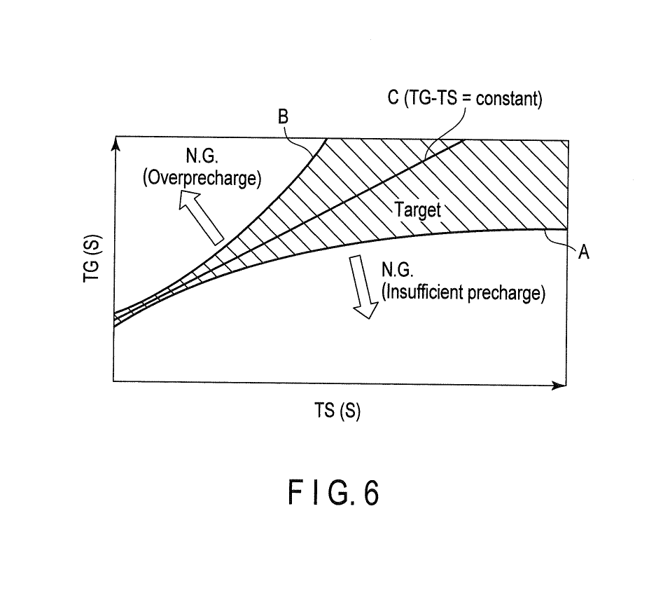

FIG. 6 is a diagram showing the relation between the time TG from the start of the precharging to the start of the activation of the sense amplifier in the reading and the time TS from the start of the flow of the cell current to the start of the activation of the sense amplifier. In this graph, the time TS is on the horizontal axis, and the time TG is on the vertical axis. The part lower than a curve A is a no-good (N.G.) region resulting from an insufficient bit line precharge time, and the part higher than a curve B is an N.G. region resulting from an excessive bit line precharge time. The part between the curves A and B is a target region, and a straight line C in the center of the target region indicates an optimum condition in which a time “TG-TS” is constant. The straight line C is better on the left side of the target region.

In the present embodiment, a monitor circuit having a replica of the sub word line SWL is provided to set the time “TG-TS” to a predetermined time. The monitor circuit uses the replica of the sub word line SWL to find a signal delay in the sub word line SWL.

Proposed 1, which uses the monitor circuit to reduce the time TS from the start of the flow of the cell current to the start of the activation of the sense amplifier, is described below.

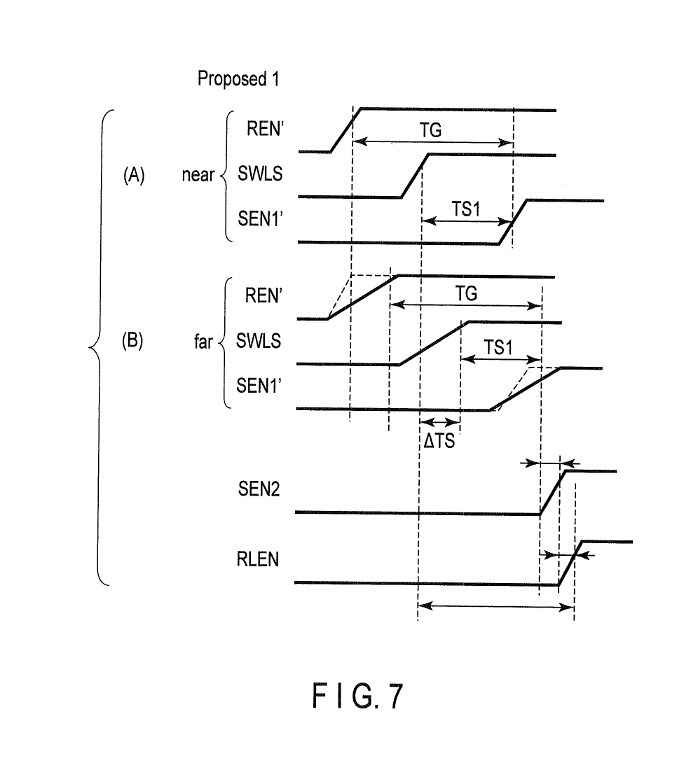

FIG. 7 is a diagram showing precharge timing during reading in Proposed 1 of the embodiment.

In Proposed 1, the rising of a read enable signal REN′ and a sense enable signal SEN1′ is delayed in accordance with the delay of the rising of the sub word line signal SWLS. Thus, the time from the start of precharging (the signal REN) to the start of the flow of the cell current (the signal SWLS) is set to an optimum time to prevent excessive precharging of the bit line. Moreover, the time TS from the start of the flow of the cell current to the start of the activation of the sense amplifier (the signal SEN1) is minimized.

The precharging operation of the bit line in Proposed 1 of the embodiment is described below.

In the memory cells near the sub word line driver SWD, the sub word line signal SWLS rises to “high” with almost no signal delay, as shown in (A) of FIG. 7. The rising of the read enable signal REN′ and the sense enable signal SEN1′ is set in accordance with the delay time of the sub word line signal SWLS by the monitor circuit having the replica of the sub word line SWL.

That is, the timing of the read enable signal REN′ is controlled in accordance with the delay time of the sub word line signal SWLS so that the precharge time will be the optimum time. As a result, the bit line can be precharged without insufficiency or excess. The sense enable signal SEN1′ is set to the time in which the bit line is precharged without insufficiency or excess. Consequently, a time TS1 from the start of the flow of the cell current to the start of the activation of the sense amplifier can be minimized, and the time of reading by the sense amplifier 12 can be reduced.

In the memory cells far from the sub word line driver SWD, the sub word line signal SWLS slowly rises to “high” due to the signal delay because the interconnect capacity is high, as shown in (B) of FIG. 7. The rising of the read enable signal REN′ and the sense enable signal SEN1′ is delayed in accordance with the delay time of the sub word line signal SWLS by the monitor circuit.

That is, the timing of the read enable signal REN′ is controlled in accordance with the delay time of the sub word line signal SWLS so that the precharge time will be the optimum time. The sense enable signal SEN1′ is set to the time in which the bit line is precharged without insufficiency or excess. Consequently, the time TS1 from the start of the flow of the cell current to the start of the activation of the sense amplifier can be minimized, and the time of reading by the sense amplifier 12 can be reduced.

Proposed 2, which uses the monitor circuit to reduce the time TS from the start of the flow of the cell current to the start of the activation of the sense amplifier, is described below.

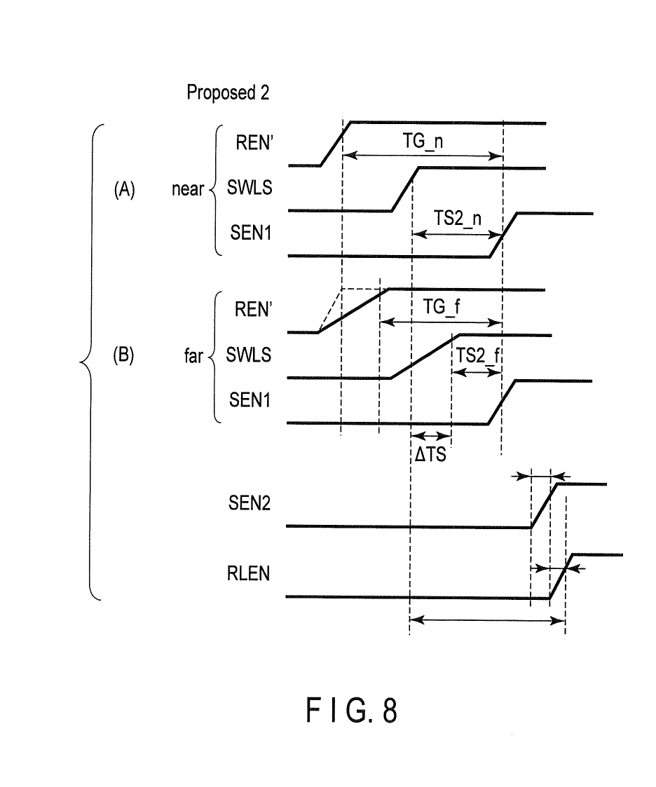

FIG. 8 is a diagram showing the precharge timing during reading in Proposed 2 of the embodiment.

In Proposed 2, the rising of the read enable signal REN′ alone is delayed in accordance with the delay of the rising of the sub word line signal SWLS. Thus, the time from the start of precharging to the start of the flow of the cell current is set to an optimum time to prevent excessive precharging of the bit line.

The precharging operation of the bit line in Proposed 2 of the embodiment is described below.

In the memory cells near the sub word line driver SWD, the sub word line signal SWLS rises to “high” with almost no signal delay, as shown in (A) of FIG. 8. The rising of the read enable signal REN′ is set in accordance with the delay time of the sub word line signal SWLS by the monitor circuit having the replica of the sub word line SWL.

That is, the rise timing of the read enable signal REN′ is controlled in accordance with the delay time of the sub word line signal SWLS so that the precharge time (TG_n-TS2_n) will be the optimum time. As a result, the bit line can be precharged without insufficiency or excess. Consequently, a time TS2_n from the start of the flow of the cell current to the start of the activation of the sense amplifier can be reduced, and the time of reading by the sense amplifier 12 can be reduced.

In the memory cells far from the sub word line driver SWD, the sub word line signal SWLS slowly rises to “high” due to the signal delay because the interconnect capacity is high, as shown in (B) of FIG. 8. The rising of the read enable signal REN′ is delayed in accordance with the delay time of the sub word line signal SWLS by the monitor circuit.

That is, the rise timing of the read enable signal REN′ is controlled in accordance with the delay time of the sub word line signal SWLS so that the precharge time (TG_f-TS2_f) will be the optimum time. Thus, the bit line can be precharged without insufficiency or excess. Consequently, the time TS2_f from the start of the flow of the cell current to the start of the activation of the sense amplifier can be reduced, and the time of reading by the sense amplifier 12 can be reduced. The precharge time (TG_n-TS2_n) is substantially equal to the precharge time (TG_f-TS2_f).

Now, the configuration and operation of the monitor circuit provided in the present embodiment are described.

The monitor circuit monitors a signal delay in the sub word line SWL caused in accordance with the position of the memory cell in the memory cell array. Moreover, the monitor circuit uses the found signal delay to set the rising of the read enable signal REN′ and the sense enable signal SEN1′. In Proposed 1, there are provided a monitor circuit which generates the read enable signal REN′, and a monitor circuit which generates the sense enable signal SEN1′.

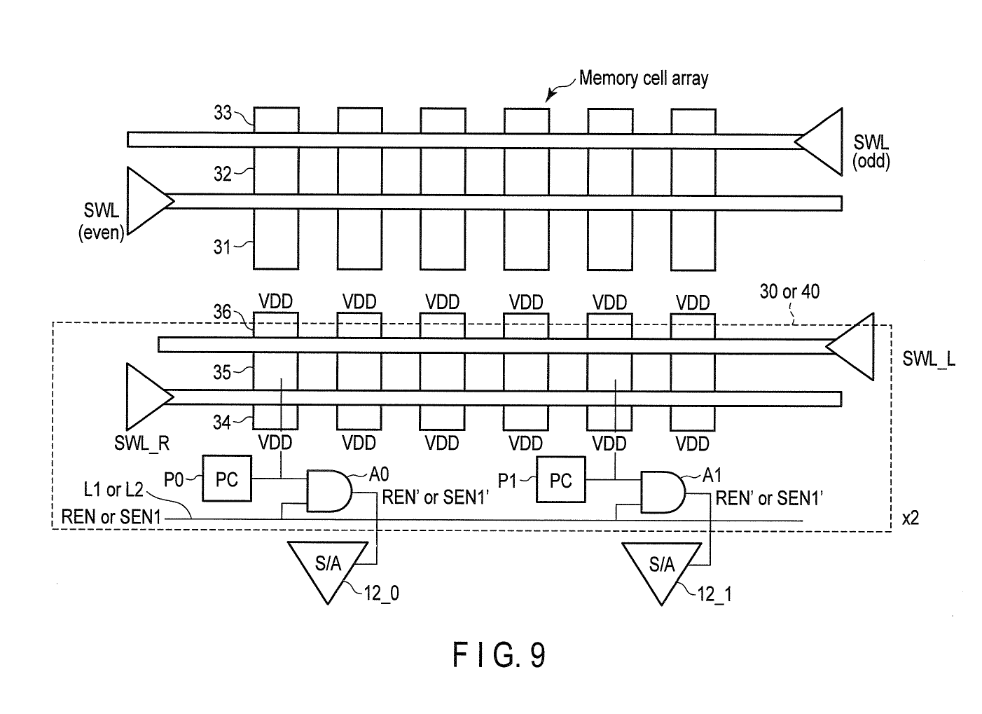

FIG. 9 is a schematic diagram showing the configurations of the memory cell array according to the embodiment and the monitor circuit according to Proposed 1.

The memory cell array has the following configuration. Activation regions (diffusion layers) 31, 32, and 33 are formed in a semiconductor substrate. Sub word lines include a sub word line SWL (even) driven from one side of the memory cell array, and a sub word line SWL (odd) driven from the other side opposite to the one side. The activation of right and left sub word line drivers in FIG. 9 is switched depending on a row to be accessed. The sub word line SWL (even) or the sub word line SWL (odd) is then driven by the sub word line driver.

The sub word line SWL is located on a gate insulating film between the activation regions 31 and 32. A select transistor including the activation regions 31 and 32 and the sub word line SWL is formed. The sub word line SWL is located on a gate insulating film between the activation regions 32 and 33. A select transistor including the activation regions 32 and 33 and the sub word line SWL is formed. A resistance change element RE such as the magnetic tunnel junction (MTJ) element is formed on the semiconductor substrate, but is not shown here.

A monitor circuit 30 which generates the read enable signal REN′ has the following configuration. The monitor circuit 30 is formed in a peripheral circuit located, for example, at the end of the memory cell array or on the periphery of the memory cell array. Activation regions (diffusion layers) 34, 35, and 36 are formed in the semiconductor substrate. The power supply voltage VDD is supplied to the activation regions 34 and 36. Replica sub word lines include a sub word line SWL_R driven from one side of the memory cell array, and a sub word line SWL_L driven from the other side opposite to the one side. The sub word lines SWL_R and SWL_L have an interconnect structure similar to that of the sub word line SWL in the memory cell array. The sub word lines SWL_R and SWL_L have an interconnect capacity (electric capacity) and electric resistance similar to those of the sub word line SWL in the memory cell array. The sub word lines SWL_R and SWL_L are made of the same material as, for example, that of the sub word line SWL in the memory cell array.

The sub word line SWL_R is located on a gate insulating film between the activation regions 34 and 35. A select transistor including the activation regions 34 and 35 and the sub word line SWL_R is formed. The sub word line SWL_L is located on the gate insulating film between the activation regions 35 and 36. A select transistor including the activation regions 35 and 36 and the sub word line SWL_L is formed. These select transistors have a structure similar to that of the select transistor in the memory cell array.

The monitor circuit 30 includes an interconnect line L1 to which the read enable signal REN is supplied. An AND circuit A0 is connected between the interconnect line L1 and the activation region 35. That is, the activation region (one end of a current path of the select transistor) 35 and a precharge circuit P0 are connected to a first input terminal of the AND circuit A0. The interconnect line L1 is connected to a second input terminal of the AND circuit A0. The read enable signal REN′ is output from an output terminal of the AND circuit A0. This read enable signal REN′ is further supplied to a sense amplifier 12_0.

An AND circuit A1 is also connected between the interconnect line L1 and the activation region 35. That is, the activation region 35 and a precharge circuit P1 are connected to a first input terminal of the AND circuit A1. The interconnect line L1 is connected to a second input terminal of the AND circuit A1. The read enable signal REN′ is output from an output terminal of the AND circuit A1. This read enable signal REN′ is supplied to a sense amplifier 12_1. A resistance change element RE such as the MTJ element may be formed in the monitor circuit 30 or does not need to be formed in the monitor circuit 30.

The monitor circuit 30 generates the read enable signal REN′ by the following operation.

Signals are not delayed much in the sub word line SWL_R near the driver which drives the sub word line SWL_R. Therefore, this sub word line SWL_R quickly rises to “high”. Accordingly, the select transistor which uses the sub word line SWL_R in this part as a gate is turned on. As a result, the power supply voltage VDD supplied to the activation region 34 is supplied to the activation region 35. A “low” is first input to the first input terminal of the AND circuit A0 from the precharge circuit P0. However, if the power supply voltage VDD is supplied to the activation region 35, the first input terminal of the AND circuit A0 becomes “high”. Here, if the read enable signal REN becomes “high” and the “high” is input to the second input terminal of the AND circuit A0, the “high” is output from the output terminal of the AND circuit A0.

The “high” output from the AND circuit A0 is supplied to the sense amplifier 12_0 as the read enable signal REN′. The read enable signal REN′ in this case rises with a little signal delay, as shown in (A) of FIG. 7.

On the other hand, signals are delayed in accordance with the distance from the driver in the sub word line SWL_R far from the driver which drives the sub word line SWL_R. Therefore, this sub word line SWL_R rises to “high” late. Accordingly, the select transistor which uses the sub word line SWL_R in this part as a gate is turned on. As a result, the power supply voltage VDD supplied to the activation region 34 is supplied to the activation region 35. A “low” is first input to the first input terminal of the AND circuit A1 from the precharge circuit P1. However, if the power supply voltage VDD is supplied to the activation region 35, the first input terminal of the AND circuit A1 becomes “high”. Here, if the read enable signal REN becomes “high” and the “high” is input to the second input terminal of the AND circuit A1, the “high” is output from the output terminal of the AND circuit A1.

The “high” output from the AND circuit A1 is supplied to the sense amplifier 12_1 as the read enable signal REN′. The read enable signal REN′ in this case slowly rises due to the signal delay caused in the sub word line SWL_R, as shown in (B) of FIG. 7.

A monitor circuit 40 which generates the sense enable signal SEN1′ has the following configuration. The monitor circuit 40 has a configuration similar to that of the monitor circuit 30 except for the following parts. The different parts of the configuration are described below.

The monitor circuit 40 includes an interconnect line L2 to which the sense enable signal SEN1 is supplied. An AND circuit A0 is connected between the interconnect line L2 and the activation region 35. That is, the activation region 35 and the precharge circuit P0 are connected to a first input terminal of the AND circuit A0. The interconnect line L2 is connected to a second input terminal of the AND circuit A0. The sense enable signal SEN1′ is output from an output terminal of the AND circuit A0. This sense enable signal SEN1′ is supplied to the sense amplifier 12_0.

An AND circuit A1 is also connected between the interconnect line L2 and the activation region 35. That is, the activation region 35 and the precharge circuit P1 are connected to the first input terminal of the AND circuit A1. The interconnect line L2 is connected to the second input terminal of the AND circuit A1. The sense enable signal SEN1′ is output from the output terminal of the AND circuit A1. This sense enable signal SEN1′ is supplied to the sense amplifier 12_1. The resistance change element RE such as the MTJ element may be formed in the monitor circuit 40 or does not need to be formed in the monitor circuit 40.

The monitor circuit 40 generates the sense enable signal SEN1′ by the following operation.

Signals are not delayed much in the sub word line SWL_R near the driver which drives the sub word line SWL_R. Therefore, this sub word line SWL_R quickly rises to “H”. Accordingly, the select transistor which uses the sub word line SWL_R in this part as a gate is turned on. As a result, the power supply voltage VDD supplied to the activation region 34 is supplied to the activation region 35. A “low” is first input to the first input terminal of the AND circuit A0 from the precharge circuit P0. However, if the power supply voltage VDD is supplied to the activation region 35, the first input terminal of the AND circuit A0 becomes “high”. Here, if the sense enable signal SEN1 becomes “high” and the “high” is input to the second input terminal of the AND circuit A0, the “high” is output from the output terminal of the AND circuit A0.

The “high” output from the AND circuit A0 is supplied to the sense amplifier 12_0 as the sense enable signal SEN1′. The sense enable signal SEN1′ in this case rises with a little signal delay, as shown in (A) of FIG. 7.

On the other hand, signals are delayed in accordance with the distance from the driver in the sub word line SWL_R far from the driver which drives the sub word line SWL_R. Therefore, this sub word line SWL_R rises to “high” late. Accordingly, the select transistor which uses the sub word line SWL_R in this part as a gate is turned on. As a result, the power supply voltage VDD supplied to the activation region 34 is supplied to the activation region 35. A “low” is first input to the first input terminal of the AND circuit A1 from the precharge circuit P1. However, if the power supply voltage VDD is supplied to the activation region 35, the first input terminal of the AND circuit A1 becomes “high”. Here, if the sense enable signal SEN1 becomes “high” and the “high” is input to the second input terminal of the AND circuit A1, the “high” is output from the output terminal of the AND circuit A1.

The “high” output from the AND circuit A1 is supplied to the sense amplifier 12_1 as the sense enable signal SEN1′. The sense enable signal SEN1′ in this case slowly rises due to the signal delay caused in the sub word line SWL_R, as shown in (B) of FIG. 7.

In Proposed 1, the read enable signal REN′ and the sense enable signal SEN1′ can be delayed in accordance with the delay time of the sub word line signal SWLS. Therefore, the time “TG-TS” from the start of precharging of the bit line to the start of the flow of the cell current can be set to an optimum time. The optimum time is a time in which the bit line is precharged without insufficiency or excess. Moreover, the time TS1 from the start of the flow of the cell current to the start of the activation of the sense amplifier can be set to a minimum time.

The precharge time of the bit line is set to the optimum time, that is, the time “TG-TS” can be set to an optimum predetermined time, so that the activation timing of the sense amplifier, that is, the timing of setting the sense enable signal SEN1′ to “high” can be earlier. Thus, the time TS1 from the start of the flow of the cell current to the start of the activation of the sense amplifier can be minimized, and the time of reading by the sense amplifier can be reduced. As a result, the time from the input of the read command to the output of the data in the memory cells can be reduced.

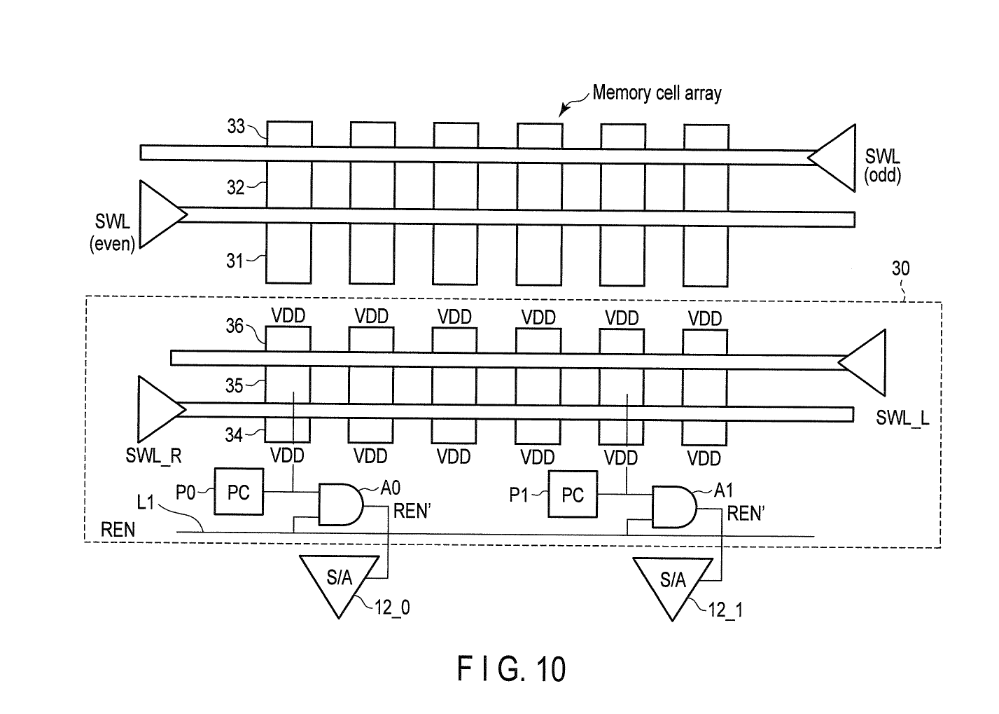

FIG. 10 is a schematic diagram showing a first configuration example of the memory cell array according to the embodiment and the monitor circuit according to Proposed 2. In the first configuration example, a monitor circuit 30 which generates the read enable signal REN′ is only provided.

The memory cell array and the monitor circuit 30 shown in FIG. 10 have configurations similar to those of the memory cell array and the monitor circuit 30 shown in FIG. 9, and are therefore not described.

In Proposed 2, the read enable signal REN′ can be delayed in accordance with the delay time of the sub word line signal SWLS. Therefore, the time “TG-TS” from the start of precharging of the bit line to the start of the flow of the cell current can be set to an optimum time. The optimum time is a time in which the bit line is precharged without insufficiency or excess.

The precharge time of the bit line is set to the optimum time, that is, the time “TG-TS” can be set to an optimum predetermined time, so that the activation timing of the sense amplifier, that is, the timing of setting the sense enable signal SEN1′ to “high” can be earlier. Thus, the time TS2 from the start of the flow of the cell current to the start of the activation of the sense amplifier can be minimized, and the time of reading by the sense amplifier can be reduced. As a result, the time from the input of the read command to the output of the data in the memory cells can be reduced.

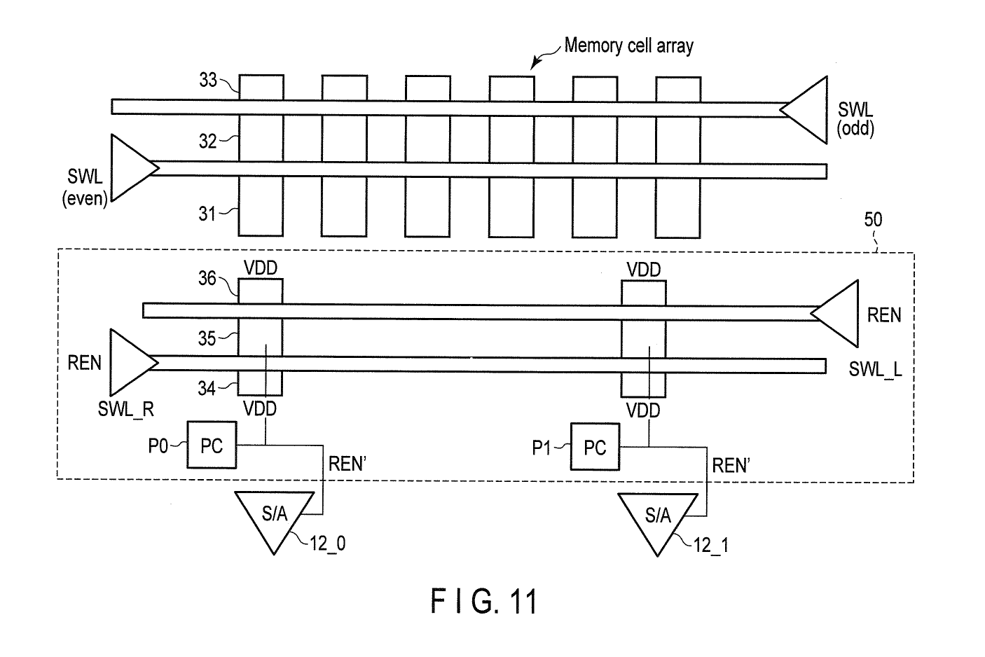

FIG. 11 is a schematic diagram showing a second configuration example of the memory cell array according to the embodiment and the monitor circuit according to Proposed 2. In the second configuration example, a monitor circuit 50 which generates the read enable signal REN′ is provided.

The memory cell array shown in FIG. 11 has a configuration similar to that of the memory cell array shown in FIG. 9, and is therefore not described.

The monitor circuit 50 which generates the read enable signal REN′ has the following configuration. The monitor circuit 50 is formed in a peripheral circuit located, for example, at the end of the memory cell array or on the periphery of the memory cell array. Activation regions 34, 35, and 36 are formed in the semiconductor substrate. The power supply voltage VDD is supplied to the activation regions 34 and 36. Replica sub word lines include a sub word line SWL_R driven from one side of the memory cell array, and a sub word line SWL_L driven from the other side opposite to the one side.

The sub word line SWL_R is located on a gate insulating film between the activation regions 34 and 35. The read enable signal REN is supplied to the sub word line SWL_R. A select transistor including the activation regions 34 and 35 and the sub word line SWL_R is formed. The sub word line SWL_L is located on the gate insulating film between the activation regions 35 and 36. The read enable signal REN is supplied to the sub word line SWL_L. A select transistor including the activation regions 35 and 36 and the sub word line SWL_L is formed.

The activation region 35 and the precharge circuit P0 are connected to the sense amplifier 12_0. The activation region 35 and the precharge circuit P1 are connected to a sense amplifier 12_1.

The monitor circuit 50 generates the read enable signal REN′ by the following operation.

Signals are not delayed much in the sub word line SWL_R near the driver which is supplied with the read enable signal REN. Therefore, this sub word line SWL_R quickly rises to “high”. Accordingly, the select transistor which uses the sub word line SWL_R in this part as a gate is turned on. As a result, the power supply voltage VDD supplied to the activation region 34 is supplied to the activation region 35, and a “high” is input to the sense amplifier 12_0 from the activation region 35 as the read enable signal REN′. The read enable signal REN′ in this case rises with a little signal delay, as shown in (A) of FIG. 8.

On the other hand, signals are delayed in accordance with the distance from the driver in the sub word line SWL_R far from the driver which is supplied with the read enable signal REN. Therefore, this sub word line SWL_R rises to “high” late. Accordingly, the select transistor which uses the sub word line SWL_R in this part as a gate is turned on. As a result, the power supply voltage VDD supplied to the activation region 34 is supplied to the activation region 35, and a “high” is input to the sense amplifier 12_1 from the activation region 35 as the read enable signal REN′. The read enable signal REN′ in this case slowly rises due to the signal delay caused in the sub word line SWL_R, as shown in (B) of FIG. 8. The configuration and advantageous effects are similar in other respects to those in the first configuration example described above.

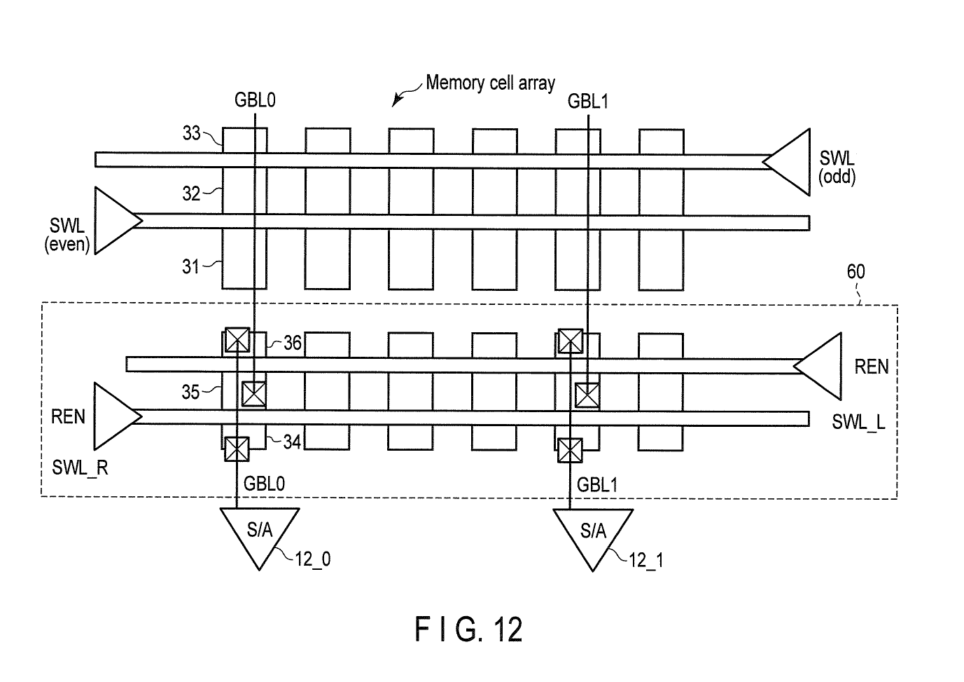

FIG. 12 is a schematic diagram showing a third configuration example of the memory cell array according to the embodiment and the monitor circuit according to Proposed 2. In the third configuration example, a monitor circuit 60 is provided. As a transistor having a gate to which the read enable signal REN is input, the monitor circuit 60 uses the select transistor which uses the sub word line SWL as a gate.

The memory cell array shown in FIG. 12 has a configuration similar to that of the memory cell array shown in FIG. 9, and is therefore not described.

The monitor circuit 60 has the following configuration. The monitor circuit 60 is formed in a peripheral circuit located, for example, at the end of the memory cell array or on the periphery of the memory cell array. Activation regions 34, 35, and 36 are formed in the semiconductor substrate. Replica sub word lines include a sub word line SWL_R driven from one side of the memory cell array, and a sub word line SWL_L driven from the other side opposite to the one side.

The sub word line SWL_R is located on a gate insulating film between the activation regions 34 and 35. A select transistor including the activation regions 34 and 35 and the sub word line SWL_R is formed. The sub word line SWL_L is located on the gate insulating film between the activation regions 35 and 36. A select transistor including the activation regions 35 and 36 and the sub word line SWL_L is formed. The read enable signal REN is supplied to the sub word lines SWL_R and SWL_L.

A global bit line GBL0 connected to the memory cell array is connected to the activation region (one end of the current path of the select transistor) 35. A global bit line GBL0 connected to the sense amplifier 12_0 is connected to the activation regions (the other ends of the current paths of the select transistors) 34 and 36. A global bit line GBL1 connected to the memory cell array is connected to the activation region 35. A global bit line GBL1 connected to the sense amplifier 12_1 is connected to the activation regions 34 and 36.

The monitor circuit 60 connects the bit lines between the sense amplifier and the memory cell array by the following operation.

Signals are not delayed much in the sub word line SWL_R near the driver which is supplied with the read enable signal REN. Therefore, this sub word line SWL_R quickly rises to “high” (read enable signal REN′). Accordingly, the select transistor which uses the sub word line SWL_R in this part as a gate is turned on. As a result, the activation region 34 and the activation region 35 are electrically connected, and the sense amplifier 12_0 is connected to the global bit line GBL0 between the memory cell arrays. Thus, precharging of the bit line including the global bit line GBL0 is started. The read enable signal REN′ in this case rises with a little signal delay, as shown in (A) of FIG. 8.

On the other hand, signals are delayed in accordance with the distance from the driver in the sub word line SWL_R far from the driver which is supplied with the read enable signal REN. Therefore, this sub word line SWL_R rises to “high” late. Accordingly, the select transistor which uses the sub word line SWL_R in this part as a gate is turned on. As a result, the activation region 34 and the activation region 35 are electrically connected, and the sense amplifier 12_1 is connected to the global bit line GBL1 between the memory cell arrays. Thus, precharging of the bit line including the global bit line GBL1 is started. The read enable signal REN′ in this case slowly rises due to the signal delay caused in the sub word line SWL_R, as shown in (B) of FIG. 8. The configuration and advantageous effects are similar in other respects to those in the first configuration example described above.

The present embodiment is a proposal regarding a method of controlling a read circuit in the resistance change memory. For example, in a memory such as an SRAM, the precharging operation of the bit line is completed before the activation of the sub word line SWL. Therefore, a reading margin is affected by the signal which decides the latch timing of the sense amplifier after the activation of the sub word line SWL. However, a resistance change memory such as an MRAM has a structure in which the cell current is passed through the bit line during the activation of the sub word line SWL, and the constant current source is connected to the bit line. In such a resistance change memory, not only the signal which decides the latch timing of the sense amplifier from the activation of the sub word line SWL but also the timing of connecting the bit line and the constant current source is important. The present embodiment proposes a method of finding the place dependence of the sub word line SWL in the chip to optimize the above-mentioned timing.

As described above, according to the present embodiment, the read enable signal (and the sense enable signal) can be delayed in accordance with the delay time of the signal transmitted on the word line. Thus, the time (precharge time) from the start of precharging of the bit line to the start of the flow of the cell current can be set to a time in which the bit line is precharged without insufficiency or excess. Thus, the time from the start of the flow of the cell current to the start of the activation of the sense amplifier can be minimized, and the reading time can be reduced.

The configurations of the whole resistance change memory, the memory cell array, the memory cell, the sense amplifier, the driver/sinker, the driver, the constant current generating circuit, and the reference current generating circuit according to the present embodiment are not limited to the configurations in the examples described above. For example, it is possible to use configurations disclosed in the specification of U.S. Pat. No. 7,649,792 and in the specification of U.S. Patent Application Publication No. 2012/0286339. The entire contents of these specifications are incorporated herein by reference.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A resistance change memory comprising:
a first memory cell comprising a first resistance change element and a first transistor, the first memory cell being connected to a bit line, the first transistor being connected to a first word line;
a sense amplifier configured to read data stored in the first memory cell;
a control circuit configured to control the reading by the sense amplifier, the control circuit outputting a first signal to control the start of precharging of the bit line, a second signal to control a cell current running through the first memory cell, and a third signal to control the start of the activation of the sense amplifier;
a second word line having an interconnect structure similar to that of the first word line; and
a first monitor circuit configured to detect a first signal delay in the second word line, the first monitor circuit outputting the first signal to the sense amplifier in accordance with the first signal delay.

2. The resistance change memory according to claim 1, wherein the second word line has an interconnect capacity similar to that of the first word line.

3. The resistance change memory according to claim 1, further comprising a second transistor having a gate to which the second word line is connected, and having a structure similar to that of the first transistor.

4. The resistance change memory according to claim 1, further comprising:
a second transistor having a gate to which the second word line is connected; and
an AND circuit comprising first and second input terminals and an output terminal, one end of a current path of the second transistor being connected to the first input terminal, the first signal being input to the second input terminal.

5. The resistance change memory according to claim 4, further comprising:
a third word line having an interconnect structure similar to that of the first word line; and
a second monitor circuit configured to detect a second signal delay in the third word line, the second monitor circuit outputting the third signal to the sense amplifier in accordance with the second signal delay.

6. The resistance change memory according to claim 1, further comprising a second transistor having a gate to which the second word line is connected, the first signal being supplied to the second word line,
wherein one end of a current path of the second transistor is connected to the sense amplifier.

7. The resistance change memory according to claim 1, further comprising a second transistor having a gate to which the second word line is connected, the first signal being supplied to the second word line,
wherein one end of a current path of the second transistor is connected to the bit line, and the other end of the current path is connected to the sense amplifier.

8. The resistance change memory according to claim 1, further comprising a memory cell array in which second memory cells comprising second resistance change elements and second transistors are arrayed, the first memory cell being included in the second memory cells in the memory cell array.

9. The resistance change memory according to claim 8, wherein the second word line is disposed at the end of the memory cell array, and connected to the second transistors in the second memory cells.

10. The resistance change memory according to claim 8, wherein the second word line is disposed in a peripheral region outside the memory cell array, and
a third transistor which has the second word line as a gate is provided in the peripheral region.

11. The resistance change memory according to claim 1, wherein the second word line is made of a same material as the first word line.

12. The resistance change memory according to claim 1, wherein a constant current source is connected to the bit line during the reading operation.

13. The resistance change memory according to claim 1, wherein the first resistance change element includes a magnetic tunnel junction (MTJ) element.

14. A resistance change memory comprising:
a first memory cell comprising a first resistance change element and a first select transistor;
a first bit line which is connected to the first memory cell and which is selected in accordance with an address signal;
a first word line which is connected to the first select transistor and which is driven in accordance with the address signal;
a second word line having an interconnect structure similar to that of the first word line;
a sense amplifier configured to read data stored in the first memory cell;
a MOS transistor connected between the first bit line and the sense amplifier;
a control circuit configured to control the reading by the sense amplifier, the control circuit outputting a first signal to control the start of precharging of the bit line, outputting, to the first and second word lines, a second signal to control a cell current running through the first memory cell, and outputting a third signal to control the start of the activation of the sense amplifier; and
a first monitor circuit configured to detect a first signal delay of the second signal in the second word line, the first monitor circuit delaying the first signal in accordance with the first signal delay and then outputting the first signal to a gate of the MOS transistor.

15. The resistance change memory according to claim 14, wherein the second word line has an interconnect capacity similar to that of the first word line.

16. The resistance change memory according to claim 14, further comprising a second select transistor having a gate to which the second word line is connected, and having a structure similar to that of the first select transistor.

17. The resistance change memory according to claim 14, further comprising:
a second select transistor having a gate to which the second word line is connected; and
an AND circuit comprising first and second input terminals and an output terminal, one end of a current path of the second select transistor being connected to the first input terminal, the first signal being input to the second input terminal.

18. The resistance change memory according to claim 14, further comprising:
a third word line having an interconnect structure similar to that of the first word line, the second signal being supplied to a gate of the third word line; and
a second monitor circuit configured to detect a second signal delay of the second signal in the third word line, the second monitor circuit delaying the third signal in accordance with the second signal delay and then outputting the third signal to the sense amplifier.

19. The resistance change memory according to claim 14, further comprising a memory cell array in which second memory cells comprising second resistance change elements and second select transistors are arrayed, the first memory cell being included in the second memory cells,
wherein the second word line is disposed at the end of the memory cell array, and connected to gates of the second select transistors in the second memory cells.

20. The resistance change memory according to claim 14 comprising a magnetoresistive random access memory (MRAM).
